(19) United States
(12) Patent Application Publication
(10) Pub. No.: US 2011/0013786 A1
(43) Pub. Date: Jan. 20, 2011

(54) MULTICHANNEL MIXER HAVING MULTIPURPOSE CONTROLS AND METERS

(75) Inventors: Leo Odom, Baton Rouge, LA (US); Olivier Limacher, Baton Rouge, LA (US)

Correspondence Address: Leason Ellis LLP, 81 Main Street, Suite 503, White Plains, NY, 10601, US

(73) Assignee: PreSonus Audio Electronics Inc., Baton Rouge, LA (US)

(21) Appl. No.: 12/819,814

(22) Filed: Jun. 21, 2010

Related U.S. Application Data
(60) Provisional application No. 61/218,877, filed on Jun. 19, 2009.

(51) Int. Cl. H03G 3/00; H04B 1/00

(52) U.S. Cl. 381/109; 381/119

(57) ABSTRACT

An audio mixer provides a set of signal processing functions operative on one or more input channels and has a mixing board, a set of discrete channel selection controls, a set of adjustment controls, and a set of visual indicators. A controller circuit responds to the selection controls to change a mode of operation between at least first and second modes of operation, responds to the adjustment controls to set a value of each signal processing function, and provides display information to the visual indicators concerning at least one of the input channels and at least one of the output channels as a function of the operating mode. The mixer arrangement has the visual indicators dynamically displaying a characteristic of each of the respective input channels in the first mode and a value of the signal processing functions operating upon the selected input channel in the second mode.

This application claims the benefit of priority of U.S. Provisional Patent Application Ser. No. 61/218,877, filed Jun. 19, 2009, which is hereby incorporated by reference as if set forth in its entirety herein.

### FIELD OF THE INVENTION

The invention relates to digital audio processing devices and more specifically the invention relates to visual presentation and control of audio channels in digital audio processing devices.

### BACKGROUND OF THE INVENTION

Audio processing devices, also known as audio mixers, are electronic devices used for mixing, processing or changing the dynamics of audio signals that are routed through audio channels. Generally, audio mixers are used in studios, Public Address (PA) systems, live performances, television, and for other audio processing and broadcasting requirements. Audio mixers enable the processing or presentation of audio channel from various audio sources simultaneously. Further, the audio channels can be mixed and their properties can be controlled. For example, vocal audio of a singer can be mixed with instrumental audio and thereafter processed to give a theater effect.

The properties of the audio channels can be monitored or controlled using the audio mixer. For example, the properties like sound level and frequency for a number of audio channels can be handled by the mixer. Generally, a large number of properties or parameters are associated with each audio channel. Therefore, the user is required to access and manage a large number of various controls to establish desired properties for the audio channels. Moreover, in case of live performances the user may be required to control the properties more frequently. As a result, the efficiency and the quality of processing are decreased.

A mechanism is therefore desirable for efficient visual presentation and control of audio channels in digital audio processing devices.

### SUMMARY

In accordance with one aspect of the invention, an audio mixer having a first plurality of input channels, a second plurality of output channels, and a set of signal processing functions is provided. One or more of the signal processing functions operate upon at least a selected one of the input channels as part of the audio mixing functionality. The mixer comprises a mixing board, a set of discrete channel selection controls on the mixing board, a set of adjustment controls moveable relative to the mixing board, and a set of visual indicators supported by the mixing board. A controller circuit is responsive to the selection controls to change a mode of operation between at least a first mode and a second mode. The controller circuit is also responsive to the adjustment controls to set a value of each signal processing function. The controller circuit is in communication with the visual indicators to provide display information to the visual indicators to dynamically display characteristics of at least one of the input channels and at least one of the output channels as a function of the mode.

The mixer arrangement of the invention has the visual indicators dynamically displaying a characteristic of each of the respective input channels in the first mode and a value of the signal processing functions operating upon the selected input channel in the second mode.

These and other aspects, features and advantages shall be apparent from the following discussion of certain embodiments of the invention taken together with the accompanying drawing figures thereof.

### BRIEF DESCRIPTION OF THE DRAWING FIGURES

Having thus described the invention in general terms, reference will now be made to the accompanying drawings, which are not necessarily drawn to scale, and wherein:

FIG. 1 is a general overview of a mixing board showing the relative layout of the mixing board, in accordance with an embodiment of the invention;

FIG. 1A is a detailed view of a first section of the mixing board, in accordance with an embodiment of the invention;

FIG. 1B is a detailed view of a second section of the mixing board, in accordance with an embodiment of the invention;

FIG. 2 is a detailed view of a combination visual indicator and adjustment control, in accordance with an embodiment of the invention; and

FIG. 3 is a block diagram of the digital audio processing modules, in accordance with an embodiment of the invention.

### DETAILED DESCRIPTION OF CERTAIN EMBODIMENTS OF THE INVENTION

By way of overview, an embodiment of the invention is described with reference to the accompanying drawings in which sixteen input channels can be individually processed and grouped into output channels including sixteen monitor channels, four grouped channels, and a pair of stereo channels. The invention provides a so-called “FAT” channel in which multiple functions can be managed on a relatively compact mixing board through the coordinated use of digital signal processing, channel management, and visual display, all managed by a control circuit. The controller provides multiple modes of operation so that the visual display can inform the user of a complex array of parameter and volume settings for one or more channels at a time. The inventive mixing arrangement can be used with mixers having different channel capabilities, such as a 24-input channel mixer. For brevity and ease of discussion, the following description is made with regard to a sixteen channel mixer, though it should be understood that embodiments of the invention can have differing numbers of channels and different signal processing capabilities and still benefit from the “FAT” channel mentioned above and described more fully below.

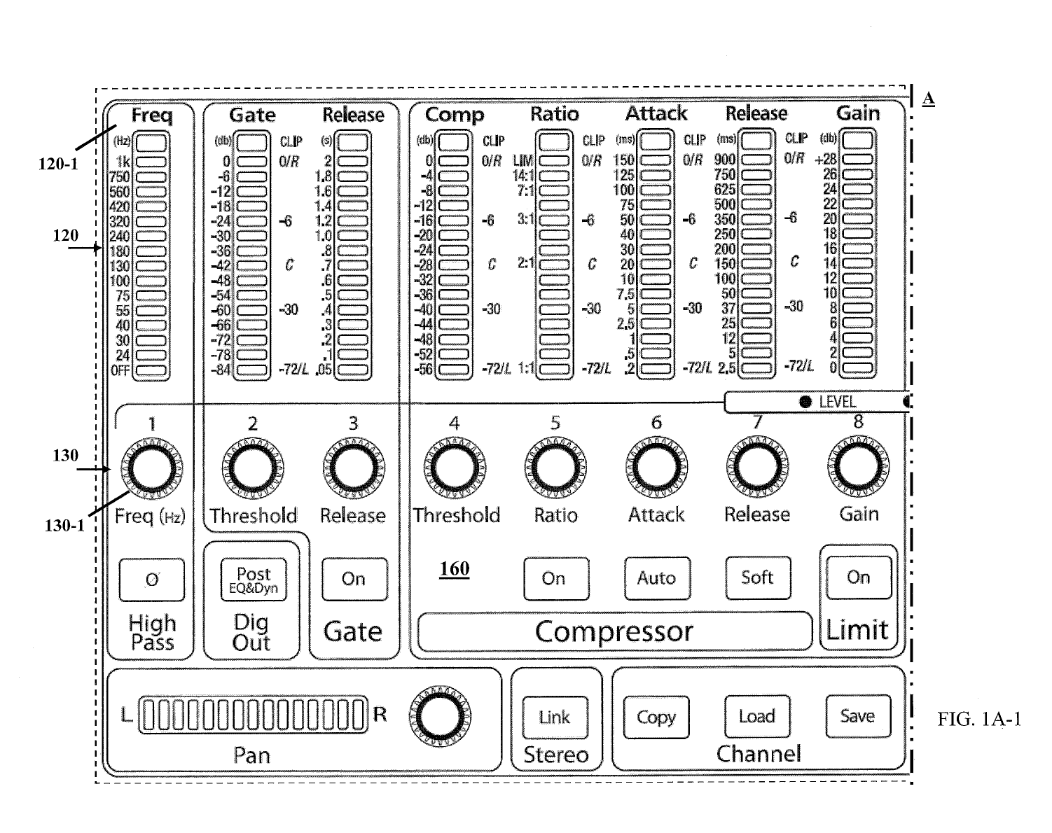

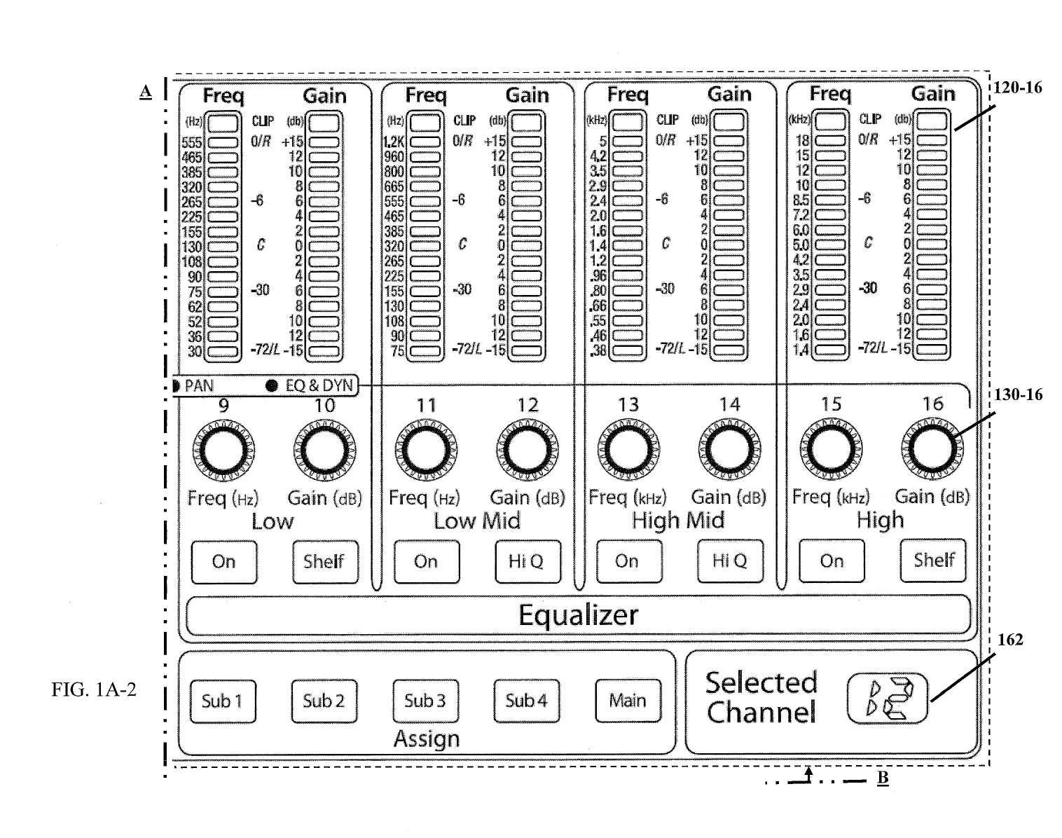

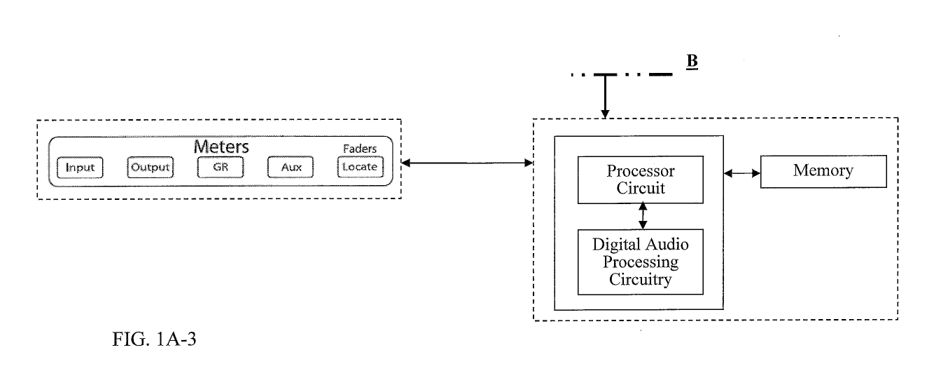

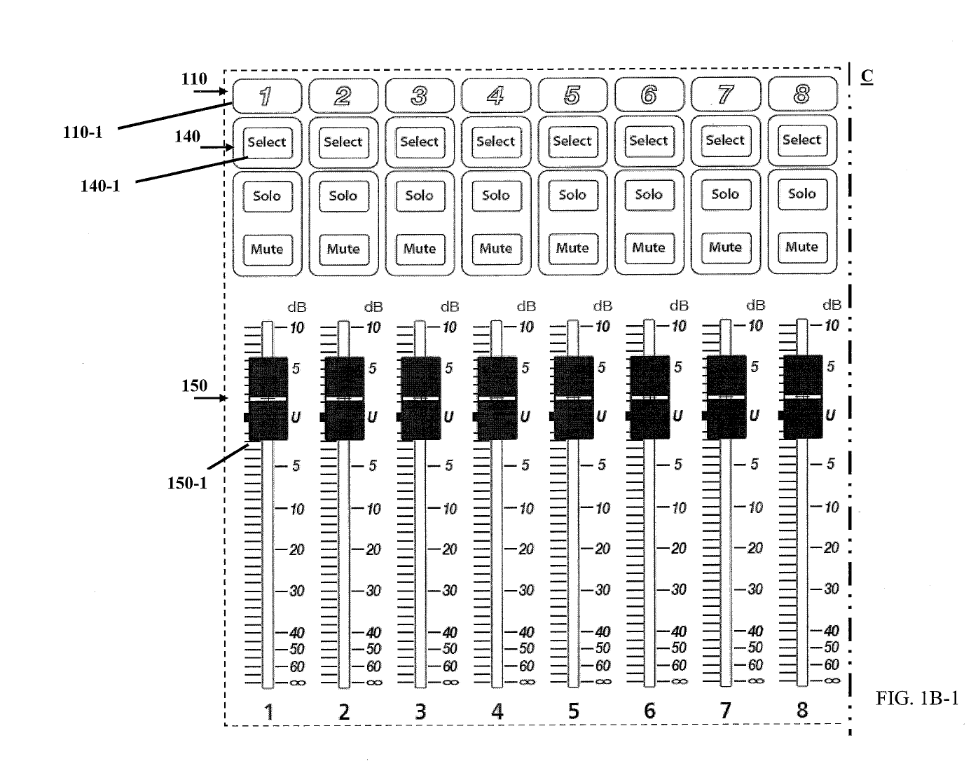

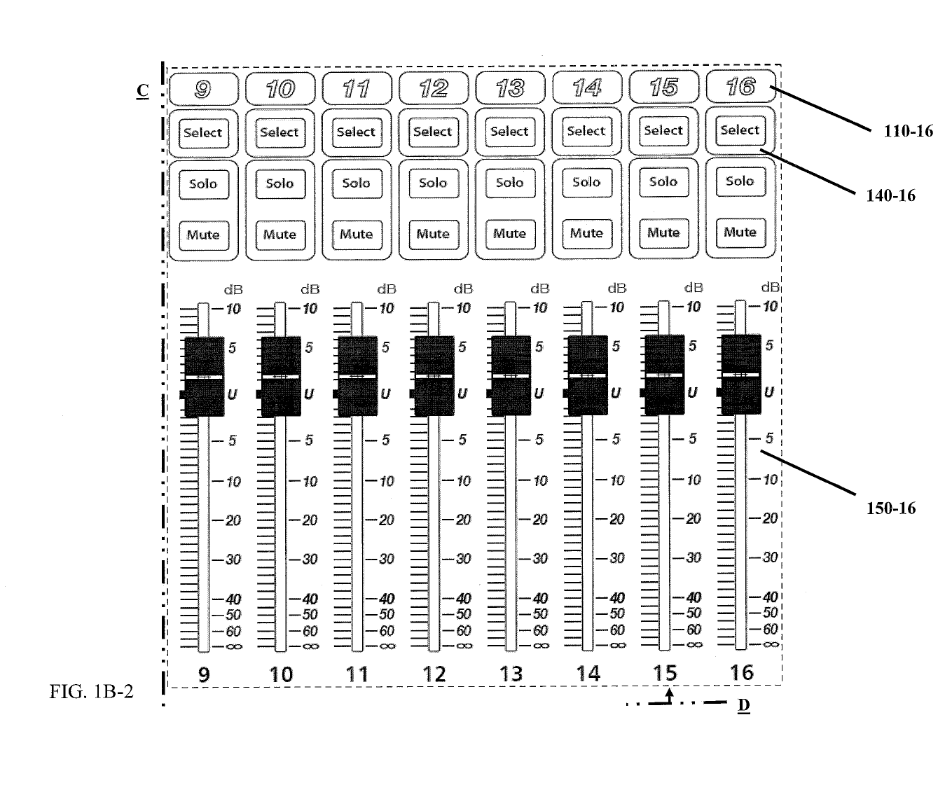

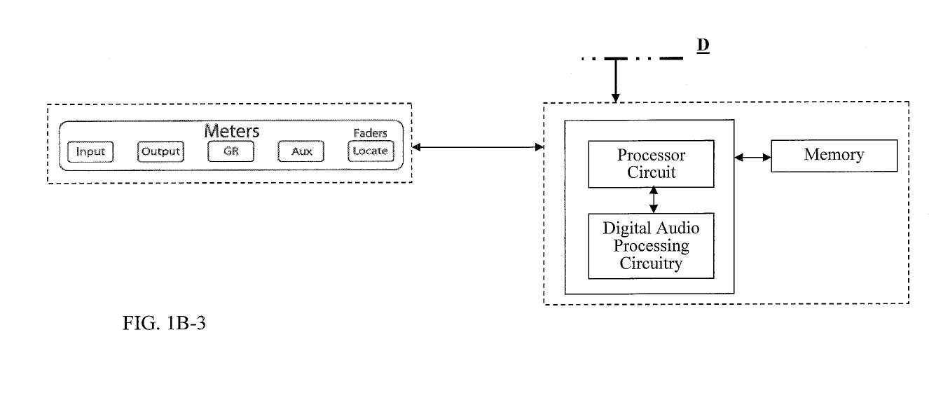

FIGS. 1, 1A and 1B illustrate an exemplary mixing board 100 of an audio mixer according to an embodiment of the invention. FIGS. 1A and 1B illustrate in detail two sections of the mixing board 100 and FIG. 1 shows the relation of the two sections to each other on the mixing board 100. The mixing board 100 of this embodiment is configured to process sixteen input signals. Each of the sixteen input signals is routed through respective audio channels. The mixing board 100 includes corresponding sets of sixteen: input channel indicia 110-1, 110-2, . . . 110-16; visual indicators 120-1, 120-2, . . . 120-16; adjustment controls 130-1, 130-2, . . . 130-16; selection controls 140-1, 140-2, . . . 140-16; and fader controls 150-1, 150-2, . . . 150-16 (each of which more generally referred to herein using its base indentifying number (e.g., 110, 120, etc.) unless a particular one of the respective set of sixteen is being discussed).

The mixing board 100 is arranged into sixteen vertical columns C-1, C-2, C-3, . . . C-16 corresponding to the sixteen audio input signals. Each vertical column includes an input channel indicia 110, visual indicator 120, adjustment control 130, selection control 140, and fader control 150, each of which is discussed in more detail below. The correspondence between the input channels that carry the audio signals, the columns, and the controls is such that, input channel 1 corresponds to vertical column C1, for example, and includes input channel indicia 110-1, visual indicator 120-1, adjustment control 130-1, selection control 140-1, and fader control 150-1. Similarly, vertical column C16 corresponds to input channel 16 and includes input channel indicia 110-16, visual indicator 120-16, adjustment control 130-16, selection control 140-16, and fader control 150-16. This arrangement of the mixing board 100 provides benefits that can be appreciated in connection with the following detailed description of the components and function of the mixing board.

The input channel indicia 110 can comprises a lamp to illuminate a present channel selection, as illustrated, or can be combined with a touch sensitive selector 140. For instance, the indicia 110 can comprise a lighted switch to identify each audio channel. An input channel indicia 110 is provided in each column C1-C16 such that input indicia 110 can be used to identify to the user which of the audio channels has been selected for signal processing adjustment by the controller circuit and for display by the visual indicators 120 described next.

The visual indicators 120 display characteristics of the audio channels. The sixteen visual indicators 120 are capable of displaying one characteristic of the sixteen audio channels, or sixteen characteristics of a single, selected audio channel. As shown in FIG. 2, in one embodiment each visual indicator 120 comprises an LED light bar. Each LED light bar includes a number of individual LED lights arranged in a column. Information concerning an audio channel and its present settings is displayed by the visual indicators. The controller circuit (not shown; see FIGS. 1A and 1B) lights one or more lights in the light column as a function of the parameter or characteristic that is to be displayed on a particular LED light bar. As will be understood, the visual indicators 120 can be implemented using indicators other than LEDs and that a column of individual LEDs is an exemplary embodiment. The more consecutive individual LED lights that are lit, the “longer” the LED light bar appears. The relative “length” of each of the LED light bars displays information about a characteristic of an audio channel. A longer light bar indicates a high value of the characteristic being displayed and a shorter light bar indicates a low value. For example, if the visual indicators 120 are in a volume display mode, a visual indicator with many of the LED lights lit creates the appearance of a “long” light bar, which indicates that the audio channel has a high volume. Conversely, a visual indicator with few LED lights lit indicates a low value of the characteristic being displayed by the visual indicator.

The fader controls 150 control the volume of the audio channels. A fader control 150 is provided for each of the audio channels in a respective fashion such that fader control 150-1 controls audio channel 1 and fader control 150-16 controls audio channel 16, etc. In the illustrated embodiment, the fader controls 150 are arranged in a vertical column that is in register with the selection controls 140, the channel indicia 110 and the visual indicators 120. Each of the faders can have a throw in the range of about 100 mm for accurate level adjustment.

The selection controls 140 allow selection of one of the audio channels for processing by the controller circuit 180. A selection control 140 is provided for each of the audio channels in a respective fashion such that selection control 140-1 selects audio channel 1 and selection control 140-16 selects audio channel 16, etc. In the illustrated embodiment, the selection controls 140 are push buttons.

The mixing board 100 includes a fast access channel 160 (herein referred to as a FAT channel) that comprises a portion of the mixing board and which is in direct communication with the controller circuit 180. The FAT channel 160 allows for adjustment of multiple characteristics of a single audio channel, the adjustment of a single characteristic of multiple audio signals, and other adjustments using the same set of adjustment controls 130. The settings are presented back to the user using the visual indicators 120. The controller circuit 180, together with its memory 190, process the adjustments (inputs received from the mixing board top panel) and present the results back to the user. The function of the adjustment controls 130 and the information displayed by the visual indicators 120 are dependent on the mode of operation of the mixing board and settings input by the user, as governed by the controller circuit 180. In one embodiment, the FAT channel 160 is capable of operating in a first, dynamic processing mode and a second, metering mode.

The visual indicators 120 include first and second sets of scale indicia 122, 124, that are on a panel of the mixing board, as shown, and their values are coordinated with the visual indicators 120 and a calibrated setting of the controller circuit 180 (see FIG. 2). These two sets of indicia assist a user as the FAT channel is used in its multiple modes. When the FAT channel 160 is operating in the dynamics processing mode, the information displayed by the visual indicators 120 can be interpreted using the first set of scale indicia 122. When the FAT channel 160 is operating in the metering mode, the information displayed by the visual indicators 120 can be interpreted using the second set of scale indicia 124. This arrangement allows the same visual indicators 120 to be used for different functions depending on the operating mode of the FAT channel 160. The FAT channel can have additional modes, the dynamics processing mode and the metering mode are two of several possible operating modes, discussed in detail below.

### Dynamics Processing Mode

In the first, dynamics processing mode the FAT channel 160 provides dynamics processing and filtering of a selected one of the sixteen input channels. Activating one of the selection controls 140 causes the controller circuit 180 to place the FAT channel 160 in the dynamics processing mode of operation for the processing of the selected input signal of the audio channel. For example, activating selection control 140-12, which is aligned in column C-12, causes the controller circuit 180 to switch to the dynamics processing mode to receive user-input settings and output to the visual indicators values based on interaction with the FAT channel 160. In this mode, dynamics processing on a given audio channel 12 can be performed. Once the user activates selection control 140-12, a display 162, which can be an LED display, indicates that channel 12 has been selected. The adjustment controls 130 can be used to adjust various characteristics of the audio input signal on any of the channels, such as channel 12. The function of each adjustment control 130 is indicated by the first set of adjustment indicia 132. As discussed above, each column C includes an adjustment control 130 and a corresponding visual indicator 120. Each respective visual indicator 120 displays the current value of the particular characteristic that the vertically aligned adjustment control 130 is capable of adjusting. Referring now to FIG. 2, the first set of scale indicia 122 allows the information being displayed by the visual indicator 120 to be interpreted and understood as representing a particular value. For example, in an illustrative embodiment, in the first, dynamics processing mode, adjustment control 130-1 provides for adjustment of a high pass filter. Accordingly, visual indicator 120-1, which is in vertical alignment with adjustment control 130-1, indicates the high pass filter threshold setting and the first set of scale indicia 122-1 is a frequency range in Hertz, for example, 24 Hz to 1 kHz.

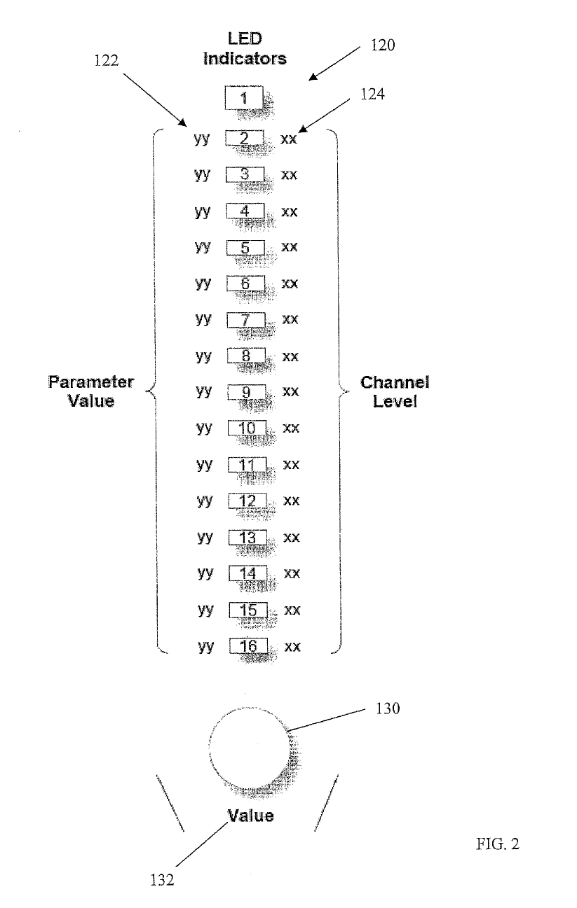

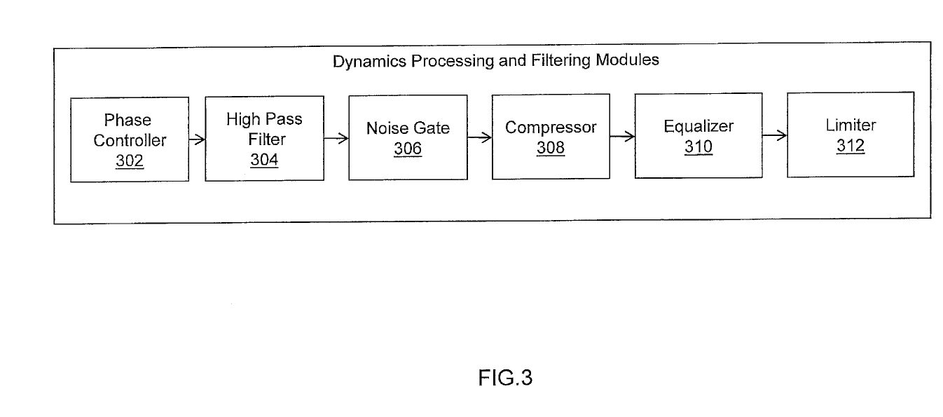

Referring to FIG. 3, in one embodiment, the dynamics processing and filtering circuitry of the mixing board 100 includes a phase controller 302, a high pass filter 304, a noise gate 306, a compressor 308, an equalizer 310, and a limiter 312. The dynamics processing and filtering circuitry can have additional modules, the phase controller, high pass filter, noise gate, compressor, equalizer, and limiter are six of several possible processing modules, discussed in detail below.

Phase controller 302 alters the phase of the audio channels. In an embodiment of the invention, phase controller inverts the phase or alters the phase by 180 degrees to correct audio channels that are out of phase. HP filter 304 sets the threshold frequencies on the audio channels. HP filter 304 attenuates the audio channels that are below a set threshold frequency. The HP filter 304 can comprise an encoder to set the frequency threshold. Noise gate 306 reduces noise levels in the audio channels. The noise gate 306 can remove the unwanted sounds from the audio channels by attenuating the audio channels below a set threshold frequency. Noise gate 306 can be engaged or disengaged for the selected audio channels and a start time and a duration of function of the noise gate 306 can be set.

The compressor 308 can comprise an amplifier in which gain is dependent on the level of the audio channels passing through it. Compression of the audio channels may be required to lower the dynamic range of an instrument or vocal to make it easier to record the audio without distortion. The adjustable parameters associated with compressor 308 can include a threshold, a compression ratio, attack speed, release time, and gain. Equalizer 310 adjusts one or a range of frequencies of the audio channels. Equalizer 310 can provide the impression of nearness or distance, ‘fatten’ or ‘thin’ a sound. Moreover, equalizer 310 can enable blending or separation between similar sounds in mixed audio channels. The equalizer 310 can comprise a frequency filter. Limiter 312 prevents the audio channels from increasing above a selected or a set frequency threshold level.

Each of the changes made through interaction with the FAT channel 160 is managed by the controller circuit 180 and stored in the memory 190. As shown in FIGS. 1A and 1B, the controller circuit 180 includes a processor circuit module 182 and a digital audio processing circuitry module 184. The processor circuit module 182 can handle the input/output signals for managing the FAT channel 160, access and write to the memory 190, and control the digital audio processing circuitry 184. The digital audio processing circuitry 184 can include the dynamics processing and filtering circuitry modules as illustrated in FIG. 3 and process the audio signals of the audio channels. The circuitry and modules and their respective functions can be integrated into a single circuit module or divided across many circuit modules. For ease of reference, the processor circuit module 182 and the digital audio processing circuitry 184 are treated as a single control circuit 180. The same settings maintained in the memory 19-0 can be recalled in other ways and immediately used without further user intervention to influence audio signals on one or more of the input channels 1-16. For instance, this can be done by selecting a stored scene using a suitable control on the mixing board top panel that operates to recall settings for one or more of a plurality of channels or channel groups from the memory and establish those settings in the signal processing path of the channels effected by that scene setting.

### Metering Mode

In the metering mode, the FAT channel 160 provides metering of the sixteen input channels. The mixing board 100 is provided with metering function controls 170 that can be used to instruct the controller circuit 180 and cause the FAT channel 160 to operate in the metering mode. In the metering mode, each of the visual indicators displays the same single characteristic of multiple input channels, and, more preferably, each of the visual indicators displays the volume or gain setting of the sixteen input channels. Each of the visual indicators 120 corresponds to an audio input channel. For example, visual indicator 120-1 corresponds to audio channel 1 and visual indicator 120-9 corresponds to audio channel 9.

The metering function controls 170 can be used to meter particular characteristics of the several audio channels concurrently. In the illustrated embodiment, metering function control 170-a causes the visual indicators 120 to display the pre-dynamics, prefader level of the input channels 1-16. The visual indicators 120 are one-to-one such that visual indicator 120-1 shows the level of channel 1, etc. Metering function control 170-e recalls the positions of the fader controls 150 as part of a stored scene. Activating the metering function control 170-e instructs the controller circuit 180 to cause the visual indicators 120 to provide indication of the current fader control positions relative to a stored fader control position for each of the input channels.

The position of the individual fader controls for each of the input channel creates a “scene.” To recreate a scene, the metering function control 170-e (“locate”) is activated, which causes the visual indicators 120 to display the current fader control position and a representation of the target fader position. For example, the visual indicator 120 has a first light that represents the current fader position and a second light that represents the target fader control position. Adjusting the fader control causes the position of the first light to move relative to the second light. The fader control is adjusted until the first and second lights merge on the visual indicator, indicating that the fader control is in the target position. In this manner, movement of the physical controls to the previously established position is re-guided by a feedback loop between the user-adjustable control, which changes the value of a particular parameter (e.g., volume) and the previously stored value in the memory 190. The feedback loop tests for a difference (positive or negative) and indicates on the visual indicators whether the physical control has been positioned so as to correspond to the previously stored value. The loop can terminate automatically once the physical control has been correctly positioned, or the user can press the metering function control 170-e again to leave the locate-settings mode.

In one example, the mixing board is used in a studio application to capture and process the audio performance of a band. Up to sixteen microphones are placed in the studio, and one or more signal lines are connected to keyboards and other instruments, in order to capture the audio produced by the various instruments and vocals of the band. The microphone cables are inputted into the 16 input channels of the mixing board. With the cables inputted into the mixing board, it is now possible to manipulate the audio channels that have the audio signals routed therethrough.

An audio channel is selected for manipulation using the selection controls 140. In this example, the user begins by viewing and adjusting the processing of audio channel 1. Pressing selection control 140-1 sends a signal to the controller circuit 180 that causes the controller circuit 180 to place the FAT channel 160 in the dynamics processing mode for dynamics processing of audio channel 1. The controller circuit 180 accesses the memory 190 to recall the current values of the audio processing being implemented by the dynamics processing circuitry. The controller circuit 180 causes the lights of the visual indicators 120 to display the current value information of the dynamics processing of audio channel 1. The controller circuit 180 also causes the LED lights of the display 162 to light in a manner to create the appearance of a number 1 to indicate the channel 1 has been selected for digital manipulation. In addition to display 162 indicating the selected channel, the selection controls 140 can be backlit buttons such that pressing the button causes the backlight to light, which because of the button being aligned in its respective column C, provides visual indication to the user which audio channel has been selected.

Once audio channel 1 has been selected using selection control 140-1, the user can begin using the adjustment controls 130 of the FAT channel 160 to cause the control circuit 180 to change the digital processing of the audio channel. The adjustment controls 130 are digital control knobs that are rotatable free of any stops and are rotatable an arbitrary number of revolutions. The physical, rotational position of the knobs is, for the most part, irrelevant because the control circuit 180 receives relative adjustment signals from the adjustment controls, e.g, based on relative movement of encoder circuit parts on the movable control and a stationary part of the control. Once the audio channel has been selected, the control circuit 180, in essence, correlates the current, initial position of the adjustment control 130 to the current, initial value of the dynamics processing operating on the audio channel. Any rotation of the adjustment control 130 from the initial position sends a signal to the control circuit 180 to either increase or decrease the value of the dynamics processing associated with that adjustment control. Thus, the user can adjust the high pass filter threshold of selected audio channel 1 using adjustment control 130-1, if desired. For example, the initial value of this characteristic is 75 Hz. Accordingly, the control circuit 180 causes the LED lights of the visual indicator 120-1 to light so that, in correspondence with scale indicia 122, the visual indicator 120-1 indicates that the current, initial value of the high pass filter threshold is 75 Hz. The control circuit 180 also “initializes” adjustment control 130-1 such that the current, initial position of the adjustment control 130-1 is now recognized by the control circuit 180 as corresponding to the value of 75 Hz. Rotating adjustment control 130-1 clockwise from the initial position sends a “positive” signal to the control circuit 180 to cause the value of the high pass filter threshold to increase. The control circuit 180 in turn sends a signal to the visual indicator 120 to cause more of the LED lights to light, thereby increasing the length of the light bar, so as to reflect the increase of the value of the high pass filter threshold. Similarly, rotating adjustment control 130-1 counterclockwise sends a “negative” signal to the control circuit 180 to cause the value high pass filter threshold to decrease and the control circuit 180 causes that decrease in the value to be reflected via a decrease in the length of the light bar of visual indicator 120-1. This same process is repeated for adjustment of each the values of the dynamics processing characteristics that are controllable via the remaining adjustment controls 130-2 through 130-16.

Once the user is satisfied with the adjusted values of the dynamics processing of audio channel 1, the user can selected the next audio channel for dynamics processing. Activating another selection control 140 causes the same adjustment controls 130 to be reinitialized to the current, initial values of the selected audio channel. For example, after manipulating the adjustment controls 130-1 through 130-16 to affect the desired adjustment of the dynamic processing values of audio channel 1, the user can next adjust the values associated with audio channel 2 by actuating selection control 140-2. Actuating selection control 140-2 sends a signal to control circuit 180 causing it to recall from memory 190 the current dynamic processing values of audio channel 2. The control circuit 180 causes the visual indicators 120, which were previously displaying the dynamic processing value information for channel 1, to now display the dynamic processing value information for channel 2. The control circuit 180 also reinitializes the adjustment controls 130 so that the current position of the adjustment controls 130 correspond to the current, initial dynamic processing values of audio channel 2. The degree that the user rotated the adjustment controls 130 in connection with adjusting the values of channel 1 is irrelevant because once the user actuates selection control 140-2, the control circuit 180 reinitializes the adjustment controls 130 such that their position at the instance of actuation of selection control 140-2 corresponds to the current dynamic processing values of audio channel 2. Rotation of the adjustment controls 130 from this initialized position affects adjustment of the dynamics processing values either by increasing or decreasing the values from the initial value. In this way, the same set of adjustment controls 130 can be used to affect adjustment of the dynamics processing values and the same set of visual indicators 120 are used to display those values for all sixteen audio channels as each of the sixteen audio channels are individually selected via selection control 140.

Continuing the discussion of this operating example, after the user has used the adjustment controls 130 and visual displays 120 to adjust and view the current dynamics processing values of the sixteen audio channels, the user can next cause the FAT channel 160 to enter the metering mode by actuating one of the meter controls 170. Depending on the metering control that is actuated, a signal is sent to the control circuit 180 to recall from memory 190 the current value of a single parameter of all sixteen audio channels. The control circuit 180 causes the visual indicators 120 to display the current value of the selected metered parameter for each of the sixteen channels on the sixteen visual indicators 120. Placing the FAT channel 160 in the metering mode allows the user to have a “global” view of the sixteen input channels so that the user can determine how the channels should be adjusted relative to each other. Adjustments to the audio channels that are caused by using the controls of the mixing board are reflected by changes in the visual indicators 120.

Accordingly, the user is provided with a mixing board 100 that can be used to adjust and meter characteristics of the sixteen audio channels. The mixing board 100 and FAT channel 160 are not limited to processing sixteen input channels and can also be used to manipulate and process analog auxiliary output channel sends, internal effects buses, combinations of various input channels that have been grouped into subgroups, auxiliary inputs, and a main output bus. Each of these channels and buses can be provided with a respective selection control button that selects it for processing by the FAT channel. It will be understood that further meters, manipulation controls, displays, and indicia can be provided on the mixing board 100.

Embodiments of the invention are described above with reference to block diagrams and schematic illustrations of methods and systems according to embodiments of the invention. It will be understood that each block of the diagrams and combinations of blocks in the diagrams can be implemented by computer program instructions. These computer program instructions can be loaded onto one or more general-purpose computers, special purpose computers, or other programmable data processing translator to produce machines, such that the instructions, which execute on the computers or other programmable data processing translator create means for implementing the functions specified in the block or blocks. Such computer program instructions can also be stored in a computer-readable memory that can direct a computer or other programmable data processing apparatus to function in a particular manner, such that the instructions stored in the computer-readable memory produce an article of manufacture including instruction means that implement the function specified in the block or blocks. Furthermore, such computer program instructions can be made available for download and/or downloaded over a communication network.

While the invention has been described in connection with what is presently considered to be the most practical and various embodiments, it is to be understood that the invention is not to be limited to the disclosed embodiments, but on the contrary, is intended to cover various modifications and equivalent arrangements included within the spirit and scope of the appended claims.

This written description uses examples to disclose the invention, including the best mode, and also to enable any person skilled in the art to practice the invention, including making and using any devices or systems and performing any incorporated methods. The patentable scope the invention is defined in the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

We claim:

1. An audio mixer having a first plurality of input channels, a second plurality of output channels, and a set of signal processing functions one or more of which are operative upon at least a selected one of the input channels, comprising:
a mixing board;
a set of discrete channel selection controls on the mixing board;
a set of adjustment controls moveable relative to the mixing board;
a set of visual indicators supported by the mixing board;
a controller circuit responsive to the selection controls to change a mode of operation between at least a first mode and a second mode, responsive to the adjustment controls to set a value of each signal processing function, and in communication with the visual indicators to provide display information to the visual indicators that dynamically display characteristics of at least one of the input channels and at least one of the output channels as a function of the mode;
wherein the visual indicators dynamically display a characteristic of each of the respective input channels in the first mode, and wherein the visual indicators dynamically display a value of the signal processing functions operating upon the selected input channel in the second mode.

2. An audio mixer of claim 1, wherein each of the visual indicators comprises a column of LEDs.

3. An audio mixer of claim 2, further comprising a set of volume controls supported by the mixing board.

4. An audio mixer of claim 3, wherein each of the selection controls, visual indicators, adjustment controls, and volume controls are disposed in vertical alignment.

5. An audio mixer of claim 4, further comprising first and second scale indicia associated with each of the visual indicators.

6. An audio mixer of claim 5, wherein for each visual indicator, adjustment control, and volume control that are in vertical alignment with one another, the first scale indicia is related to the volume control and the visual indicator indicates a position of the volume control in the first mode, and the second scale indicia is related to the signal processing function that is adjustable by the adjustment control and the visual indicator displays a value of the signal processing function operating upon the input channel in the second mode.

7. An audio mixer of claim 1, wherein the signal processor is a digital signal processor that operates upon an input signal that is routed through a selected input channel.

8. An audio mixer of claim 1, wherein the adjustment controls are rotatable free of any stops and are rotatable an arbitrary number of revolutions.
